(19) United States
(12) Patent Application Publication
(10) Pub. No.: US 2024/0387302 A1
(43) Pub. Date: Nov. 21, 2024

(54) SEMICONDUCTOR DEVICE AND INVERTER DEVICE

(71) Applicant: Mitsubishi Electric Corporation, Tokyo (JP)

(72) Inventors: Yu FUKUNAGA, Tokyo (JP); Yoshiaki TAKEWAKI, Tokyo (JP); Yasutaka SHIMIZU, Tokyo (JP)

(73) Assignee: Mitsubishi Electric Corporation, Tokyo (JP)

(21) Appl. No.: 18/429,353

(22) Filed: Jan. 31, 2024

(30) Foreign Application Priority Data
May 17, 2023 (JP) 2023-081362

(51) Int. Cl. H01L 21/66

(52) U.S. Cl. CPC H01L 22/32

(57) ABSTRACT

A semiconductor device includes: a semiconductor chip, a first emitter electrode, a second emitter electrode, a third emitter electrode, a first emitter wire, a second emitter wire, and a plurality of third emitter wires. The first emitter wire connects the first emitter electrode and an emitter pattern of the semiconductor chip. The second emitter wire connects the second emitter electrode and the emitter pattern of the semiconductor chip. The plurality of third emitter wires connect the third emitter electrode and the emitter pattern of the semiconductor chip. A diameter of the second emitter wire is larger than a diameter of the first emitter wire and a diameter of each of the plurality of third emitter wires. The first emitter wire is located away from the plurality of third emitter wires.

### BACKGROUND OF THE INVENTION

### Field of the Invention

The present disclosure relates to semiconductor devices and inverter devices.

### Description of the Background Art

A semiconductor device includes a life monitoring wire to predict the life of the semiconductor device. A power semiconductor module disclosed in Japanese Patent Application Laid-Open No. 2005-286009 includes a dummy wire to predict separation of a wire.

The end of the life of the semiconductor device due to deterioration of a wire is predicted by measuring changes in potentials of a main wire and the life monitoring wire. The changes in potentials, however, include an effect of deterioration of the main wire, so that the life cannot accurately be predicted.

### SUMMARY

It is an object of the present disclosure to provide a semiconductor device that achieves a high life prediction accuracy.

A semiconductor device according to the present disclosure includes: a semiconductor chip, a first emitter electrode, a second emitter electrode, a third emitter electrode, a first emitter wire, a second emitter wire, and a plurality of third emitter wires. The semiconductor chip includes an emitter pattern. The first emitter wire connects the first emitter electrode and the emitter pattern of the semiconductor chip. The second emitter wire connects the second emitter electrode and the emitter pattern of the semiconductor chip. The plurality of third emitter wires connect the third emitter electrode and the emitter pattern of the semiconductor chip. A diameter of the second emitter wire is larger than a diameter of the first emitter wire and a diameter of each of the plurality of third emitter wires. The first emitter wire is located away from the plurality of third emitter wires.

The semiconductor device that achieves a high life prediction accuracy is provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a configuration of a semiconductor device according to Embodiment 1;

FIG. 2 is a plan view illustrating a configuration of a semiconductor device according to Embodiment 3;

FIG. 3 is a diagram illustrating a heat generation distribution in a semiconductor chip when the semiconductor device is driven; and

FIG. 4 is a plan view illustrating a configuration of a semiconductor device according to Embodiment 4.

### DESCRIPTION OF THE PREFERRED EMBODIMENTS

### Embodiment 1

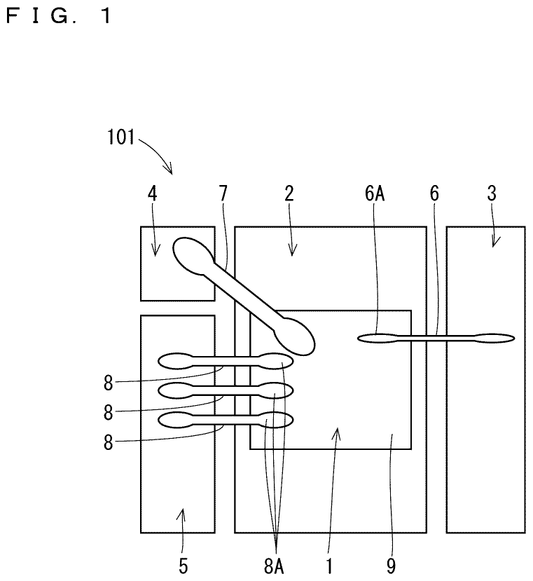

FIG. 1 is a plan view illustrating a configuration of a semiconductor device 101 according to Embodiment 1.

The semiconductor device 101 includes a semiconductor chip 1, a collector electrode 2, a first emitter electrode 3, a second emitter electrode 4, a third emitter electrode 5, a first emitter wire 6, a second emitter wire 7, and a plurality of third emitter wires 8.

The semiconductor chip 1 includes a vertical semiconductor element (not illustrated) that allows a current to flow between an upper surface and a lower surface thereof. The semiconductor element is an insulated gate bipolar transistor (IGBT). The semiconductor element may be a reverse-conducting IGBT (an RC-IGBT) including an IGBT and a freewheeling diode formed on a single semiconductor chip 1. The semiconductor chip 1 is formed of a semiconductor, such as Si, for example. The semiconductor may be a so-called wide bandgap semiconductor, such as SiC, GaN, Ga₂O₃, and diamond. The semiconductor chip 1 in Embodiment 1 is a power semiconductor chip. The semiconductor chip 1 includes an emitter pattern 9 and a collector pattern (not illustrated). The emitter pattern 9 is formed in a front surface of the semiconductor chip 1 and electrically connected to an emitter of the IGBT. While the emitter pattern 9 is provided in the entire front surface of the semiconductor chip 1 in FIG. 1 for ease of description, the emitter pattern 9 is actually provided at a predetermined location in the front surface of the semiconductor chip 1. The collector pattern is formed in a back surface of the semiconductor chip 1 and electrically connected to a collector of the IGBT. The emitter pattern 9 and the collector pattern are formed of metal. The collector pattern is bonded to the collector electrode 2 via a bonding material (not illustrated). That is to say, the semiconductor chip 1 is mounted over the collector electrode 2. The bonding material has conductivity. The bonding material is solder, for example.

The collector electrode 2, the first emitter electrode 3, the second emitter electrode 4, and the third emitter electrode 5 are formed on a front surface of an insulating member (not illustrated), for example. The insulating member is a resin layer provided on a ceramic substrate or a heat sink, for example. The collector electrode 2, the first emitter electrode 3, the second emitter electrode 4, and the third emitter electrode 5 are formed of a conductive material, such as metal.

The first emitter wire 6 connects the first emitter electrode 3 and the emitter pattern 9 of the semiconductor chip 1. The second emitter wire 7 connects the second emitter electrode 4 and the emitter pattern 9 of the semiconductor chip 1. The plurality of third emitter wires 8 connect the third emitter electrode 5 and the emitter pattern 9 of the semiconductor chip 1. The first emitter wire 6 and the second emitter wire 7 are monitoring wires to detect deterioration of the wires. The third emitter wires 8 are main wires electrically connected to a main terminal (not illustrated) of the semiconductor device 101. The first emitter wire 6, the second emitter wire 7, and the third emitter wires 8 are metal wires, for example.

A diameter of the second emitter wire 7 is larger than a diameter of the first emitter wire 6 and a diameter of each of the third emitter wires 8. The diameter of the second emitter wire 7 is 500 μm, for example. The diameter of the first emitter wire 6 and the diameter of each of the third emitter wires 8 are each 300 μm, for example. The area of bonding between the second emitter wire 7 and the semiconductor chip 1 is larger than the area of bonding between each of the third emitter wires 8 and the semiconductor chip 1.

The second emitter wire 7 having such a configuration is more strongly affected by a difference in coefficient of linear expansion from the semiconductor chip 1 than the third emitter wires 8 when the semiconductor device 101 is in operation. The second emitter wire 7 breaks sooner than the third emitter wires 8.

The first emitter wire 6 is located away from the third emitter wires 8. For example, a distance between an end 6A of the first emitter wire 6 and an end 8A of each of the third emitter wires 8 each connected to the emitter pattern 9 is greater than a distance between ends 8A of two adjacent third emitter wires 8 each connected to the emitter pattern 9. The first emitter wire 6 and the plurality of third emitter wires 8 are respectively arranged on one side and on the other side opposing each other in plan view of the emitter pattern.

The first emitter wire 6 having such a configuration is less likely to allow a current to flow therethrough than the third emitter wires 8. The first emitter wire 6 is thus less likely to be deteriorated than the third emitter wires 8.

The life is predicted by a unit to which the semiconductor device 101 is mounted when the semiconductor device 101 is in operation. In other words, the unit has a life prediction function. The unit measures a potential difference between the first emitter wire 6 and the second emitter wire 7. The unit predicts the life by comparing a measured value and an initial value to determine a difference.

Taken together, the semiconductor device 101 according to Embodiment 1 includes the semiconductor chip 1, the first emitter electrode 3, the second emitter electrode 4, the third emitter electrode 5, the first emitter wire 6, the second emitter wire 7, and the plurality of third emitter wires 8. The semiconductor chip 1 includes the emitter pattern 9. The first emitter wire 6 connects the first emitter electrode 3 and the emitter pattern 9 of the semiconductor chip 1. The second emitter wire 7 connects the second emitter electrode 4 and the emitter pattern 9 of the semiconductor chip 1. The plurality of third emitter wires 8 connect the third emitter electrode 5 and the emitter pattern 9 of the semiconductor chip 1. The diameter of the second emitter wire 7 is larger than the diameter of the first emitter wire 6 and the diameter of each of the plurality of third emitter wires 8. The first emitter wire 6 is located away from the plurality of third emitter wires 8.

When the semiconductor device 101 is in operation, the above-mentioned unit measures the potential difference between the first emitter wire 6 that is less likely to allow a current to flow therethrough than the other emitter wires and the second emitter wire 7 that is more likely to be deteriorated than the other wires. The unit accurately measures a degree of deterioration of the wires without being affected by deterioration of the third emitter wires 8 as the main wires. The semiconductor device 101 enables accurate estimation of most recent quality deterioration of wire bonding on the semiconductor chip 1 to achieve a high life prediction accuracy.

### Embodiment 2

The diameter of the first emitter wire 6 in Embodiment 2 is smaller than the diameter of each of the plurality of third emitter wires 8. The diameter of the second emitter wire 7 is larger than the diameter of the first emitter wire 6 and the diameter of each of the third emitter wires 8 as in Embodiment 1. A diameter of a metal wire as the first emitter wire 6 is 200 μm, for example. A diameter of a metal wire as the second emitter wire 7 is 500 μm, for example. A diameter of a metal wire as each of the third emitter wires 8 is 300 μm, for example.

The area of contact between the first emitter wire 6 and the emitter pattern 9 of the semiconductor chip 1 is reduced. This enables reduction in area of the semiconductor chip 1 and, further, miniaturization of the semiconductor device 101.

### Embodiment 3

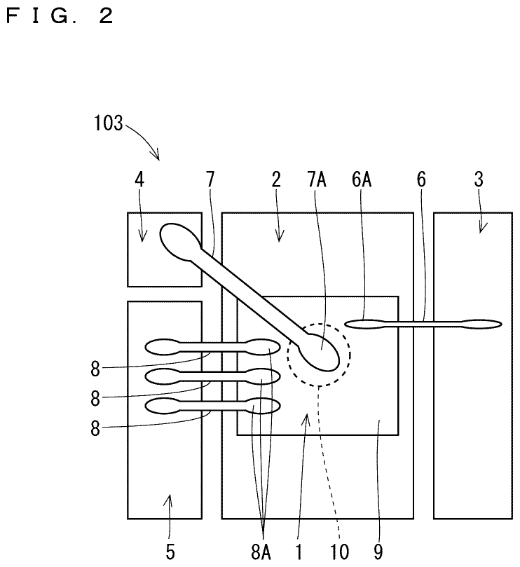

FIG. 2 is a plan view illustrating a configuration of a semiconductor device 103 according to Embodiment 3. The emitter pattern 9 of the semiconductor chip 1 is provided in a region including a central portion 10 of the semiconductor chip 1 in plan view. An end 7A of the second emitter wire 7 is bonded to the emitter pattern 9 in the central portion 10 of the semiconductor chip 1. In other words, a location of bonding between the second emitter wire 7 and the emitter pattern 9 is in the central portion 10 of the semiconductor chip 1.

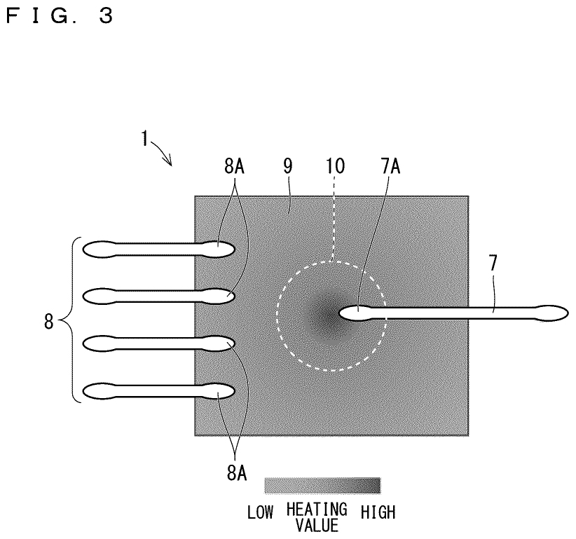

FIG. 3 is a diagram illustrating a heat generation distribution in the semiconductor chip 1 when the semiconductor device 103 is driven. A heating value is the highest in the central portion 10 of the semiconductor chip 1 and decreases with decreasing distance from a peripheral edge portion thereof. The second emitter wire 7 bonded to the central portion 10 of the semiconductor chip 1 is more strongly affected by a difference in coefficient of linear expansion from the semiconductor chip 1 than the wires bonded to the other portions. Certainty of deterioration of the second emitter wire 7 thus increases. As a result, the life prediction accuracy is improved. The semiconductor device 103 enables prediction of a failure occurring due to breakage of a wire.

### Embodiment 4

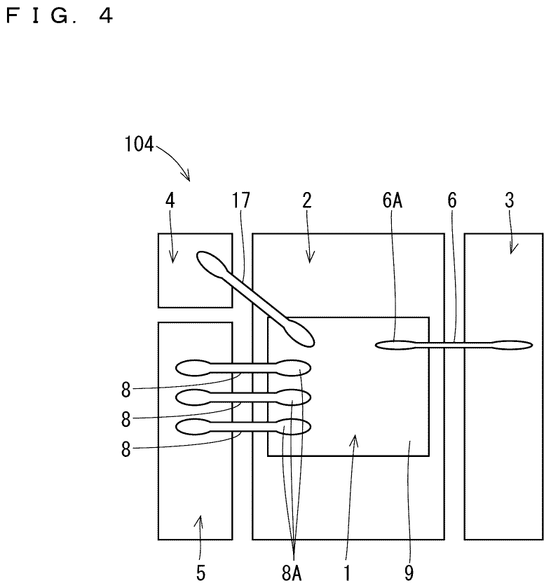

FIG. 4 is a plan view illustrating a configuration of a semiconductor device 104 according to Embodiment 4. A second emitter wire 17 is formed of a material having a lower strength than a material forming the first emitter wire 6 and the third emitter wires 8. The second emitter wire 17 is formed of pure aluminum not containing nickel, for example. The third emitter wires 8 are formed of aluminum containing trace amounts of nickel, for example.

According to such a configuration, the second emitter wire 17 is more strongly affected by a difference in coefficient of linear expansion from the semiconductor chip 1 than the third emitter wires 8. The second emitter wire 17 is thus deteriorated sooner than the third emitter wires 8. In a case where the configuration in Embodiment 3 is applied to the semiconductor device 104, deterioration of the second emitter wire 17 is accelerated. The life prediction accuracy is thus improved. A failure of the semiconductor device 104 as a whole can be predicted.

### Embodiment 5

An inverter device according to Embodiment 5 includes the semiconductor device shown in any of Embodiments 1 to 4. The inverter device can diagnose deterioration and predict the life of the semiconductor device built therein.

Embodiments of the present disclosure can freely be combined with each other and can be modified or omitted as appropriate.

Various aspects of the present disclosure will collectively be described below as appendices.

### Appendix 1

A semiconductor device comprising:
a semiconductor chip including an emitter pattern;
a first emitter electrode;
a second emitter electrode;
a third emitter electrode;
a first emitter wire connecting the first emitter electrode and the emitter pattern of the semiconductor chip;
a second emitter wire connecting the second emitter electrode and the emitter pattern of the semiconductor chip; and
a plurality of third emitter wires connecting the third emitter electrode and the emitter pattern of the semiconductor chip, wherein
a diameter of the second emitter wire is larger than a diameter of the first emitter wire and a diameter of each of the plurality of third emitter wires, and
the first emitter wire is located away from the plurality of third emitter wires.

### Appendix 2

The semiconductor device according to Appendix 1, wherein
the diameter of the first emitter wire is smaller than the diameter of each of the plurality of third emitter wires.

### Appendix 3

The semiconductor device according to Appendix 1 or 2, wherein
the emitter pattern is provided in a region including a central portion of the semiconductor chip in plan view, and
an end of the second emitter wire is connected to the emitter pattern in the central portion of the semiconductor chip.

### Appendix 4

The semiconductor device according to any one of Appendices 1 to 3, wherein
the second emitter wire is formed of a material having a lower strength than a material forming the first emitter wire and the plurality of third emitter wires.

### Appendix 5

The semiconductor device according to any one of Appendices 1 to 4, wherein
a distance between an end of the first emitter wire and an end of each of the plurality of third emitter wires each connected to the emitter pattern is greater than a distance between ends of two adjacent third emitter wires of the plurality of third emitter wires each connected to the emitter pattern.

### Appendix 6

The semiconductor device according to any one of Appendices 1 to 5, wherein
the first emitter wire and the plurality of third emitter wires are respectively arranged on one side and on the other side opposing the one side of the emitter pattern in plan view of the emitter pattern.

### Appendix 7

An inverter device comprising
the semiconductor device according to any one of Appendices 1 to 6.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor chip including an emitter pattern;
a first emitter electrode;
a second emitter electrode;
a third emitter electrode;
a first emitter wire connecting the first emitter electrode and the emitter pattern of the semiconductor chip;
a second emitter wire connecting the second emitter electrode and the emitter pattern of the semiconductor chip; and
a plurality of third emitter wires connecting the third emitter electrode and the emitter pattern of the semiconductor chip, wherein
a diameter of the second emitter wire is larger than a diameter of the first emitter wire and a diameter of each of the plurality of third emitter wires, and
the first emitter wire is located away from the plurality of third emitter wires.

2. The semiconductor device according to claim 1, wherein
the diameter of the first emitter wire is smaller than the diameter of each of the plurality of third emitter wires.

3. The semiconductor device according to claim 1, wherein
the emitter pattern is provided in a region including a central portion of the semiconductor chip in plan view, and
an end of the second emitter wire is connected to the emitter pattern in the central portion of the semiconductor chip.

4. The semiconductor device according to claim 1, wherein
the second emitter wire is formed of a material having a lower strength than a material forming the first emitter wire and the plurality of third emitter wires.

5. The semiconductor device according to claim 1, wherein
a distance between an end of the first emitter wire and an end of each of the plurality of third emitter wires each connected to the emitter pattern is greater than a distance between ends of two adjacent third emitter wires of the plurality of third emitter wires each connected to the emitter pattern.

6. The semiconductor device according to claim 1, wherein
the first emitter wire and the plurality of third emitter wires are respectively arranged on one side and on the other side opposing the one side of the emitter pattern in plan view of the emitter pattern.

7. An inverter device comprising
the semiconductor device according to claim 1.
